(19) United States
(12) Patent Application Publication
(10) Pub. No.: US 2013/0118563 A1
(43) Pub. Date: May 16, 2013

(54) SOLAR PHOTOVOLTAIC DEVICE AND A PRODUCTION METHOD FOR THE SAME

(71) Applicants: Suk Jae Jee, Seoul (KR); Hi Sun Pak, Seoul (KR); Dong Keun Lee, Seoul (KR)

(72) Inventors: Suk Jae Jee, Seoul (KR); Hi Sun Pak, Seoul (KR); Dong Keun Lee, Seoul (KR)

(73) Assignee: LG INNOTEK CO., LTD., Seoul (KR)

(21) Appl. No.: 13/520,957

(22) PCT Filed: Jan. 6, 2011
(86) PCT No.: PCT/KR11/00093

§ 371 Date: Sep. 12, 2012

(30) Foreign Application Priority Data
Jan. 6, 2010 (KR) 10-2010-0000994

(51) Int. Cl. H01L 31/0224; H01L 31/18

(52) U.S. Cl. CPC H01L 31/022441; H01L 31/18
USPC 136/252; 438/98

(57) ABSTRACT

Disclosed are a solar cell apparatus and a method for manufacturing the same. The solar cell apparatus includes a support substrate, a first back electrode on the support substrate, a light absorbing part on the first back electrode, a high resistance buffer on the light absorbing part, and a barrier layer extending from the high resistance buffer and provided on a lateral side of the light absorbing part.

### TECHNICAL FIELD

The embodiment relates to a solar cell apparatus and a method for manufacturing the same.

### BACKGROUND ART

Recently, as energy consumption is increased, a solar cell has been developed to convert solar energy into electrical energy.

In particular, a CIGS-based cell, which is a PN hetero junction apparatus having a substrate structure including a glass substrate, a metallic back electrode layer, a P type CIGS-based light absorbing layer, a high resistance buffer layer, and an N type window layer, has been extensively used.

### DISCLOSURE

### Technical Problem

The embodiment provides a solar cell apparatus and a method for manufacturing the same, capable of blocking leakage current and representing improved photoelectric transformation efficiency.

### Technical Solution

According to the embodiment, there is provided a solar cell apparatus including a support substrate, a first back electrode on the support substrate, a light absorbing part on the first back electrode, a high resistance buffer on the light absorbing part, and a barrier layer extending from the high resistance buffer and provided on a lateral side of the light absorbing part.

According to the embodiment, there is provided a solar cell apparatus including a support substrate, a back electrode layer on the support substrate, a light absorbing layer provided on the back electrode layer and provided therein with a through hole, a high resistance buffer layer provided on the light absorbing layer and provided on an internal lateral side of the through hole, and a window layer on the high resistance buffer layer.

According to the embodiment, there is provided a method for manufacturing a solar cell apparatus, which includes forming a back electrode layer on a support substrate, forming a light absorbing layer on the back electrode layer, forming a through hole in the light absorbing layer, forming a high resistance buffer layer on the light absorbing layer and on an internal lateral side of the through hole, and forming an open region, which partially overlaps with the through hole and exposes the back electrode layer, in the high resistance buffer layer.

### Advantageous Effects

As described above, the solar cell apparatus according to the embodiment includes a barrier layer. The lateral side of the light absorbing part can be insulated by the barrier layer. Therefore, the solar cell apparatus according to the embodiment can block leakage current through the lateral side of the light absorbing part.

Therefore, according to the solar cell apparatus of the embodiment, leakage current can be blocked and improved power generation efficiency can be obtained.

In particular, the barrier layer can include zinc oxide that is not doped with impurities, so that the barrier layer represents high resistance. Therefore, the barrier layer can effectively block the leakage current.

In addition, an additional layer need not be formed in order to form the barrier layer. In other words, the barrier layer can be formed when the high resistance buffer is formed. Therefore, according to the embodiment, the solar cell apparatus having the improved electrical characteristic can be easily provided.

### DESCRIPTION OF DRAWINGS

FIG. 1 is a plan view showing a solar cell apparatus according to the embodiment;

FIG. 2 is a sectional view taken along line A-A′ of FIG. 1; and

FIGS. 3 to 7 are sectional views showing a method for manufacturing the solar cell apparatus according to the embodiment.

### BEST MODE

### Mode for Invention

In the description of the embodiments, it will be understood that, when a layer (or film), a region, a pattern, or a structure is referred to as being “on” or “under” another substrate, another layer (or film), another region, another pad, or another pattern, it can be “directly” or “indirectly” on the other substrate, layer (or film), region, pad, or pattern, or one or more intervening layers may also be present. Such a position of the layer has been described with reference to the drawings. The thickness and size of each layer shown in the drawings may be exaggerated, omitted or schematically drawn for the purpose of convenience or clarity. In addition, the size of elements does not utterly reflect an actual size.

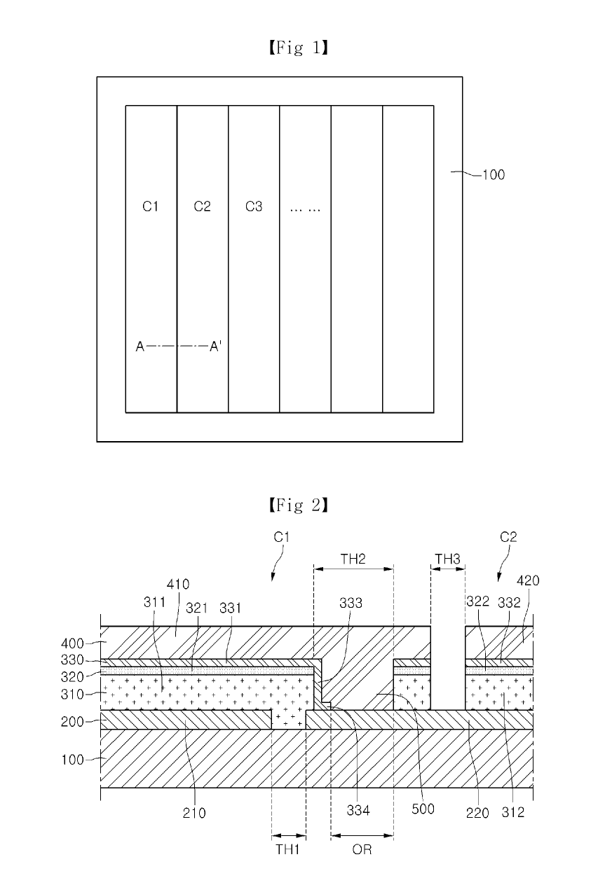

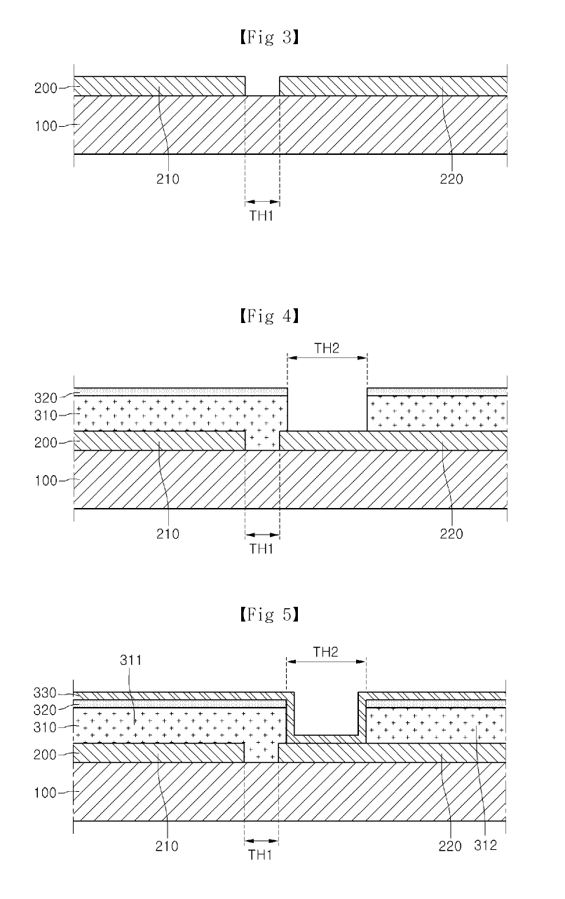

FIG. 1 is a plan view showing a solar cell apparatus according to the embodiment, and FIG. 2 is a sectional view taken along line A-A′ of FIG. 1.

Referring to FIGS. 1 and 2, the solar cell apparatus includes a support substrate 100, a back electrode layer 200, a light absorbing layer 310, a buffer layer 320, a high resistance buffer layer 330, a barrier layer 333, a window layer 400, and a connection part 500.

The support substrate 100 has a plate shape, and supports the back electrode layer 200, the light absorbing layer 310, the buffer layer 320, the high resistance buffer layer 330, the window layer 400, and the connection part 500.

The support substrate 100 may include an insulating material. For instance, the support substrate 100 may be a glass substrate, a plastic substrate or a metal substrate. In detail, the support substrate 100 may include a soda lime glass substrate. In addition, the support substrate 100 may be transparent. The support substrate 100 may be rigid or flexible.

The back electrode layer 200 is provided on the support substrate 100. The back electrode layer 200 is a conductive layer. A material constituting the back electrode layer 200 may include metal such as molybdenum (Mo).

The back electrode layer 200 may include at least two layers. In this case, the layers constituting the back electrode layer 200 may include the same material or different materials.

The back electrode layer 200 is provided therein with first through holes TH1. The through hole TH1 is an open region to expose the top surface of the support substrate 100. When viewed in a plan view, the first through hole TH1 may extend in one direction.

The first through hole TH1 has a width in the range of about 80 μm to about 200 μm.

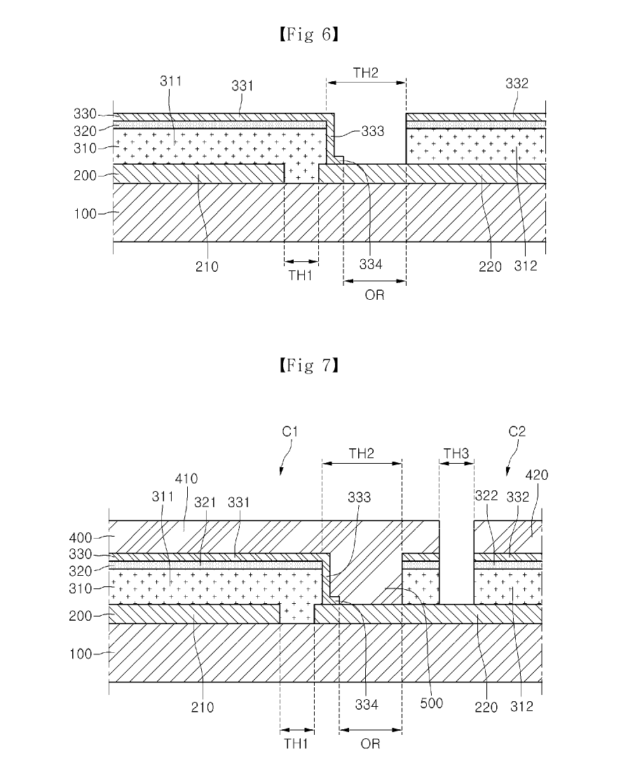

The back electrode layer 200 is divided into a plurality of back electrodes 210, 220, . . . , and 22N by the first through hole TH1. In other words, the back electrodes 210, 220, . . . , and 22N are defined by the first through hole TH1. In FIG. 3, only the first and second back electrodes 210 and 220 among the back electrodes 210, 220, . . . , and 22N are shown.

The back electrodes 210, 220, . . . , and 22N are spaced apart from each other by the first through hole TH1. The back electrodes 210, 220, . . . , and 22N are arranged in the form of a strip.

In addition, the back electrodes 210, 220, . . . , and 22N may be arranged in the form of a matrix. In this case, when viewed in a plan view, the first through hole TH1 may be provided in the form of a lattice.

The light absorbing layer 310 is provided on the back electrode layer 200. In addition, material constituting the light absorbing layer 310 is filled in the first through hole TH1.

The light absorbing layer 310 may include group I-III-VI-based compounds. For example, the light absorbing layer 310 may have a Cu—In—Ga—Se (Cu (In, Ga) Se₂; CIGS)-based crystal structure, a Cu—In—Se-based crystal structure, or a Cu—Ga—Se-based crystal structure.

The energy band gap of the light absorbing layer 310 may be in the range of about 1.eV to about 1.8 eV.

The buffer layer 320 is provided on the light absorbing layer 310. The buffer layer 320 includes cadmium sulfide (CdS), and the energy band gap of the buffer layer 320 is in the range of about 2.2 eV to about 2.4 eV.

The light absorbing layer 310 and the buffer layer 320 are formed therein with second through holes TH2. The second through holes TH2 are formed through the light absorbing layer 310 and the buffer layer 320. In addition, the second through holes TH2 are open regions to expose the top surface of the back electrode layer 200.

The second through holes TH2 are adjacent to the first through holes TH1. In other words, when viewed in a plan view, portions of the second through holes TH2 are formed beside the first through holes TH1.

Each second through holes TH2 may have a width in the range of about 80 μm to about 200 μm.

The light absorbing layer 310 defines a plurality of light absorbing parts 311, 312, . . . , and 31N by the second through holes TH2. In other words, the light absorbing layer 310 is divided into the light absorbing parts 311, 312, . . . , and 31N by the second through holes TH2.

Similarly, the buffer layer 320 defines a plurality of buffers 321, 322, . . . , and 32N by the second through holes TH2.

The high resistance buffer layer 330 is provided on the buffer layer 320. In addition, the high resistance buffer layer 330 is provided inside the second through hole TH2. The high resistance buffer layer 330 includes zinc oxide (i-ZnO) that is not doped with impurities. The high resistance buffer layer 330 has energy band gap in the range of about 3.1 eV to about 3.3 eV.

The high resistance buffer layer 330 has high resistance. In detail, the high resistance buffer layer 330 has resistance higher than those of the window layer 400 and the connection part 500. In more detail, the high resistance buffer layer 330 may have resistance about 10⁵ times to about 10⁷ times greater than those of the window layer 400 and the connection part 500. The high resistance buffer layer 330 may have a thickness in the range of about 20 nm to about 100 nm.

The high resistance buffer layer 330 is divided into a plurality of high resistance buffer layers 331, 332, . . . , and 33N, the barrier layer 333, and a dummy part 334 by an open region overlapping with the second through hole TH2.

The open region OR expose the top surface of the back electrode layer 200 by removing a portion of the high resistance buffer layer 330. The open region OR may be offset from the second through hole TH2. In other words, the center of the open region OR may be offset from the center of the second through hole TH2.

The open region OR may have a width narrower than that of the second through hole TH2.

The barrier layer 333 extends from the high resistance buffer 331 provided on the first light absorbing part 311, so that the barrier layer 333 is provided on the lateral side of the first light absorbing part 311. The barrier layer 333 is formed integrally with the first high resistance buffer 331, and interposed between the first light absorbing part 311 and the connection part 500.

The barrier layer 333 has high resistance similarly to that of the first high resistance buffer 331. In other words, the barrier layer 333 has resistance higher than that of the connection part 500. In detail, the barrier layer 333 may have resistance about 10⁵ to about 10⁷ times greater than that of the connection part 500. For example, the barrier layer 333 has resistance in the range of about 50M Ω to about 200M Ω.

The barrier layer 333 has a thickness in the range of about 20 nm to about 100 nm similarly to that of the high resistance buffer layer 330.

The dummy part 334 extends along the top surface of the back electrode layer 200 from the barrier layer 333. In detail, the dummy part 334 extends from the barrier layer 333 while making contact with the top surface of the second back electrode 220. The dummy part 334 is formed integrally with the barrier layer 333.

The window layer 400 is provided on the high resistance buffer layer 330. The window layer 400 is transparent, and includes a conductive layer. For example, material constituting the window layer 400 may include Al doped ZnO (AZO).

The window layer 400 is provided therein with third through holes TH3. The third through hole TH3 is an open region to expose the top surface of the back electrode layer 200. For example, the third through hole TH3 has a width in the range of about 80 μm to about 200 μm.

The third through holes TH3 are adjacent to the second through holes TH2. The third through holes TH3 are formed beside the second through holes TH2. In other words, when viewed in a plan view, the third through holes TH3 are formed beside the second through holes TH2.

The window layer 400 is divided into a plurality of widows 410, 420, . . . , and 42N by the third through hole TH3. In other words, the windows 410, 420, . . . , and 42N are defined by the third through hole TH3.

The widows 410, 420, . . . , and 42N have shapes corresponding to those of the back electrodes 210, 220, . . . , and 22N. In other words, the windows 410, 420, . . . , and 42N are provided in the form of a strip. In addition, the windows 410, 420, . . . , and 42N may be arranged in the form of a matrix.

A plurality of cells C1, C2, . . . , and CN are defined by the third through holes TH3. In detail, the cells C1, C2, . . . , and CN are defined by the second through hole TH2 and the third through hole TH3. In other words, the solar cell apparatus according to the embodiment is divided into the cells C1, C2, . . . , and CN by the second and third through holes TH2 and TH3.

In other words, the solar cell apparatus according to the embodiment includes the cells C1, C2, . . . , and CN. For example, the solar cell apparatus according to the embodiment includes the first and second cells C1 and C2 provided on the support substrate 100.

The first cell C1 includes the first back electrode 210, the first light absorbing part 311, the first buffer 321, the first high resistance buffer 331, and the first window 410.

The first back electrode 210 is provided on the support substrate 100. The first light absorbing part 311, the first buffer 321, and the first high resistance buffer 331 are sequentially stacked on the first back electrode 210. The first window 410 is provided on the first high resistance buffer 331.

The first back electrode 210 faces the first window 410 while interposing the first light absorbing part 311 between the first back electrode 210 and the first window 410.

The second cell C2 is provided on the support substrate 100 while being adjacent to the first cell C1. The second cell C2 includes the second back electrode 220, the second light absorbing part 312, the second buffer 322, the second high resistance buffer 332, and the second window 420.

The second back electrode 220 is provided on the support substrate 100 while being spaced apart from the first back electrode 210. The second light absorbing part 312 is provided on the second back electrode 220 while being spaced apart from the first light absorbing part 311. The second window 420 is provided on the second high resistance buffer 332 while being spaced apart from the first window 410.

The second light absorbing part 312 and the second window 420 expose a portion of the top surface of the second back electrode 220 while covering the second back electrode 220.

The connection part 500 is provided inside the second through hole TH2.

The connection part 500 extends downward from the window layer 400 while directly making contact with the back electrode layer 200. For example, the connection part 500 extends downward from the first window 410 to directly make contact with the second electrode 220.

Accordingly, the connection part 500 connects windows and back electrodes, which constitute the cells C1, C2, . . . , and CN adjacent to each other, with each other. In other words, the connection part 500 connects the first window 410 with the second back electrode 220.

The connection part 500 is formed integrally with the windows 410, 420, . . . , and 42N. In other words, material constituting the connection part 500 is the same as material constituting the window layer 400.

As described above, the barrier layer 333 has high resistance. Accordingly, the barrier layer 333 insulates the lateral side of the connection part 500. In addition, the barrier layer 333 insulates the lateral sides of the light absorbing parts 311, 312, . . . , and 31N.

The barrier layer 333 can be interposed between the light absorbing parts 311, 312, . . . , and 31N and the connection parts 500 to block leakage current between the lateral side of the light absorbing parts 311, 312, . . . , and 31N and the connection parts 500. For example, the barrier layer 333 can block leakage current flowing from the connection par 500 to the first back electrode 210 through the lateral side of the first light absorbing art 311.

Therefore, the solar cell apparatus according to the embodiment can represent improved electrical characteristics.

In addition, it is unnecessary to sufficiently increase the width of the first through hole TH1 in order to block the leakage current. In other words, even if the width of the first through hole TH1 is decreased, the leakage current can be effectively blocked by the barrier layer 333.

Therefore, the width of the first through hole TH1 can be reduced, and a dead zone, in which power generation is impossible, can be reduced in the solar cell apparatus according to the embodiment.

Accordingly, the solar cell apparatus according to the embodiment has improved power generation efficiency.

FIGS. 3 to 7 are sectional views showing a method for manufacturing the solar cell apparatus according to the embodiment. The method for manufacturing the solar cell apparatus will be described by making reference to the prior description about the solar cell apparatus.

Referring to FIG. 3, the back electrode layer 200 is formed on the support substrate 100. The first through hole TH1 is formed by patterning the back electrode layer 200. Therefore, the back electrodes 210, 220, . . . , and 22N are formed on the support substrate 100. The back electrode layer 200 is patterned by a laser.

The first through hole TH1 exposes the top surface of the support substrate 100 and may have the width in the range of about 80 μm to about 200 μm.

In addition, an additional layer such as an anti-diffusion layer may be interposed between the support substrate 100 and the back electrode layer 200. In this case, the first through hole TH1 exposes the top surface of the additional layer.

Referring to FIG. 4, the light absorbing layer 310 and the buffer layer 320 are sequentially formed on the back electrode layer 200.

The light absorbing layer 310 may be formed through a sputtering process or an evaporation scheme.

For example, the light absorbing layer 310 may be formed through various schemes such as a scheme of forming a Cu (In, Ga) Se₂ (CIGS) based-light absorbing layer 310 by simultaneously or separately evaporating Cu, In, Ga, and Se and a scheme of performing a selenization process after a metallic precursor film has been formed.

Regarding the details of the selenization process after the formation of the metallic precursor layer, the metallic precursor layer is formed on the back contact electrode 200 through a sputtering process employing a Cu target, an In target, or a Ga target.

Thereafter, the metallic precursor layer is subject to the selenization process so that the Cu (In, Ga) Se₂ (CIGS) based-light absorbing layer 310 is formed.

In addition, the sputtering process employing the Cu target, the In target, and the Ga target and the selenization process may be simultaneously performed.

In addition, a CIS or a CIG light absorbing layer 310 may be formed through a sputtering process employing only Cu and In targets or only Cu and Ga targets and the selenization process.

Thereafter, the buffer layer 400 may be formed after depositing cadmium sulfide on the light absorbing layer 310 through a sputtering process or a CBD (chemical bath deposition) scheme.

Thereafter, the second through hole TH2 is formed by removing portions of the light absorbing layer 310 and the buffer layer 320.

The second through hole TH2 may be formed by a mechanical device such as a tip or a laser device.

For example, the light absorbing layer 310 and the buffer layer 320 may be patterned by a tip having a width in the range of about 40 μm to about 180 μm. In addition, the second through hole TH2 may be formed by a laser having a wavelength in the range of about 200 nm to about 600 nm.

In this case, the second through hole TH2 may have a width in the range of about 100 μm to about 200 μm. The second through hole TH2 exposes a portion of the top surface of the back electrode layer 200.

Referring to FIG. 5, zinc oxide is deposited on the buffer layer 320 and inside the second through hole TH2 through a sputtering process, thereby forming the high resistance buffer layer 330.

Referring to FIG. 6, a portion of the high resistance buffer layer 330 is removed by a laser or a mechanical scribing process, thereby forming the open region OR. The open region OR partially overlaps with the second through hole TH2. In other words, the open region OR is offset from the second through hole TH2. In detail, the center of the open region OR may be offset from the center of the second through hole TH2.

Therefore, the barrier layer 333 is formed on the lateral side of the light absorbing parts 311, 312, . . . , and 31N, and the dummy part 334 may be formed on the back electrode layer 200.

In the process of forming the open region OR, it is difficult to exactly adjust the positions of the scribing pattering or the laser patterning so that only the barrier layer 333 remains. Accordingly, since the high resistance buffer layer 330 is patterned so that a slight marginal part remains, the dummy part 334 is formed. Therefore, if the high resistance buffer layer 330 is very accurately patterned through the scribing process so that only the barrier layer 333 remains, the dummy part 334 may be omitted.

Referring to FIG. 7, the window layer 400 is formed on the high resistance buffer layer 330. In this case, material constituting the window layer 400 is filled in the second through hole TH2.

In order to form the window layer 400, transparent conductive material is stacked on the high resistance buffer layer 330. The transparent conductive material is fully filled in the second through hole TH2. The transparent material may Al-doped zinc oxide.

Therefore, the connection part 500 extending from the window layer 400 to directly make contact with the back electrode layer 200 is formed in the second through hole TH2.

Thereafter, the third through hole TH3 is formed by removing a portion of the window layer 400. In other words, the window layer 400 is patterned, so that the windows 410, 420, . . . , and 42N and the cells C1, C2, . . . , and CN are defined.

The third through hole TH3 has a width in the range of about 80 μm to about 200 μm.

As described above, the barrier layer 333 is formed, thereby providing the solar cell apparatus having high efficiency.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

### INDUSTRIAL APPLICABILITY

The solar cell apparatus and the method for manufacturing the same according to the embodiment are applicable to a solar power generation field.

1. A solar cell apparatus comprising:
a support substrate;
a first back electrode on the support substrate;
a light absorbing part on the first back electrode;
a high resistance buffer on the light absorbing part; and
a barrier layer extending from the high resistance buffer and provided on a lateral side of the light absorbing part.

2. The solar cell apparatus of claim 1, further comprising:
a second back electrode beside the first back electrode;
a window on the high resistance buffer; and
a connection part extending from the window and connected to the second back electrode,
wherein the barrier layer is interposed between the light absorbing part and the connection part.

3. The solar cell apparatus of claim 2, wherein resistance of the barrier layer is greater than resistance of the connection part.

4. The solar cell apparatus of claim 2, wherein resistance of the barrier layer is about 10⁵ times to about 10⁷ times greater than resistance of the connection part.

5. The solar cell apparatus of claim 2, further comprising a dummy part extending from the barrier layer along a top surface of the second back electrode.

6. The solar cell apparatus of claim 5, wherein the high resistance buffer, the barrier layer, and the dummy part are integrally formed with each other.

7. The solar cell apparatus of claim 5, wherein the high resistance buffer, the barrier layer, and the dummy part include zinc oxide.

8. The solar cell apparatus of claim 1, further comprising a buffer interposed between the light absorbing part and the high resistance buffer,
wherein the barrier layer covers a lateral side of the buffer and a lateral side of the light absorbing layer.

9. The solar cell apparatus of claim 1, wherein a thickness of the barrier layer is in a range of about 20 nm to about 100 nm.

10. A solar cell apparatus comprising:
a support substrate;
a back electrode layer on the support substrate;
a light absorbing layer provided on the back electrode layer and provided therein with a through hole;
a high resistance buffer layer provided on the light absorbing layer and provided on an internal lateral side of the through hole; and
a window layer on the high resistance buffer layer.

11. The solar cell apparatus of claim 10, wherein the high resistance buffer layer has an open region to expose a bottom surface of the through hole.

12. The solar cell apparatus of claim 11, wherein the open region has a width smaller than a width of the through hole.

13. The solar cell apparatus of claim 11, wherein an entire portion of the open region overlaps with the through hole.

14. The solar cell apparatus of claim 10, wherein the high resistance buffer layer comprises:
a high resistance buffer on the light absorbing layer;
a barrier layer on the internal lateral side of the through hole; and
a dummy part on a bottom surface of the through hole.

15. The solar cell apparatus of claim 14, further comprising a connection part extending from the window layer, connected to the back electrode layer, and provided in the through hole,
wherein the barrier layer is directly connected to the connection part.

16. A method for manufacturing a solar cell apparatus, the method comprising:
forming a back electrode layer on a support substrate;
forming a light absorbing layer on the back electrode layer;
forming a through hole in the light absorbing layer;
forming a high resistance buffer layer on the light absorbing layer and on an internal lateral side of the through hole; and
forming an open region, which partially overlaps with the through hole and exposes the back electrode layer, in the high resistance buffer layer.

17. The method of claim 16, wherein, in the forming of the through hole, the light absorbing layer is patterned by using a mechanical device or a laser so that a portion of the back electrode layer is exposed.

18. The method of claim 16, wherein, in the forming of the open region, the high resistance layer is patterned by using a mechanical device or a laser so that a portion of the back electrode layer is exposed.

19. The method of claim 16, wherein a width of the open region is smaller than a width of the through hole.

20. The method of claim 16, wherein a center of the open region is offset from a center of the through hole.
